(19) United States
(12) Patent Application Publication
(10) Pub. No.: US 2026/0107389 A1
(43) Pub. Date: Apr. 16, 2026

(54) ELECTRONIC DEVICE

(71) Applicant: ROHM CO., LTD., Kyoto-shi (JP)

(72) Inventor: Hiroki MIYAZAKI, Kyoto-shi (JP)

(21) Appl. No.: 19/422,002

(22) Filed: Dec. 16, 2025

Related U.S. Application Data
(63) Continuation of application No. PCT/JP2024/019001, filed on May 23, 2024.

(30) Foreign Application Priority Data
Jun. 21, 2023 (JP) 2023-101348

(51) Int. Cl. H05K 1/181; H05K 3/28

(52) U.S. Cl. CPC H05K 1/181; H05K 3/284

(57) ABSTRACT

An electronic device includes: an electronic component; a support member that supports the electronic component; a wiring section formed on the support member; and a conductive bonding member that bonds a terminal of the electronic component to the wiring section. A body of the electronic component includes a side surface facing in a first direction perpendicular to the thickness direction, and a bottom surface facing the support member. The terminal includes a side electrode extending from a first edge to a second edge of the side surface in the thickness direction. The conductive bonding member includes a top in the thickness direction. A distance between the top and the bottom surface in the thickness direction is at most 1/2 of a dimension of the side electrode in the thickness direction.

### TECHNICAL FIELD

### The present disclosure relates to an electronic device

### BACKGROUND ART

An electronic device provided with a plurality of electronic components has been conventionally known. JP-A-2018-181961 discloses an example of a conventional electronic device. The electronic device disclosed in JP-A-2018-181961 includes a circuit structure and a sealing resin. The circuit structure has an electronic component mounted on a circuit board. The electronic component is a chip resistor or a chip capacitor, for example. The circuit board is obtained by forming wiring with use of a conductor pattern made of copper (Cu) or silver (Ag), for example, on an insulating base such as resin or ceramics. The electronic component is mounted on the circuit board via solder, for example. The sealing resin is epoxy resin, for example, and seals the circuit structure.

### BRIEF DESCRIPTION OF THE DRAWINGS

FIG. 1 is a plan view showing an electronic device according to a first embodiment

FIG. 2 corresponds to the plan view of FIG. 1, with a sealing resin indicated by imaginary lines.

FIG. 3 corresponds to the plan view of FIG. 2, but omits the sealing resin and indicates a plurality of electronic components with imaginary lines.

FIG. 4 is a bottom view showing an electronic device according to the first embodiment.

FIG. 5 is a front view showing the electronic device according to the first embodiment, with the sealing resin indicated by imaginary lines.

FIG. 6 is a left-side view showing the electronic device according to the first embodiment, with the sealing resin indicated by imaginary lines.

FIG. 7 is a right-side view showing the electronic device according to the first embodiment, with the sealing resin indicated by imaginary lines.

FIG. 8 is a cross-sectional view along line VIII-VIII in FIG. 2.

FIG. 9 is a partially enlarged cross-sectional view showing a part of FIG. 8.

FIG. 10 is a partially enlarged cross-sectional view showing a part of FIG. 8.

FIG. 11 is a cross-sectional view showing a step of a method for manufacturing the electronic device according to the first embodiment, and corresponds to the cross section in FIG. 8.

FIG. 12 is a cross-sectional view showing a step of the method for manufacturing the electronic device according to the first embodiment, and corresponds to the cross section in FIG. 8.

FIG. 13 is a cross-sectional view showing a step of the method for manufacturing the electronic device according to the first embodiment, and corresponds to the cross section in FIG. 8.

FIG. 14 is a cross-sectional view showing a step of the method for manufacturing the electronic device according to the first embodiment, and corresponds to the cross section in FIG. 8.

FIG. 15 is a cross-sectional view showing a step of the method for manufacturing the electronic device according to the first embodiment, and corresponds to the cross section in FIG. 8.

FIG. 16 is a cross-sectional view showing a step of the method for manufacturing the electronic device according to the first embodiment, and corresponds to the cross section in FIG. 8.

FIG. 17 is a cross-sectional view showing a step of the method for manufacturing the electronic device according to the first embodiment, and corresponds to the cross section in FIG. 8.

FIG. 18 is a cross-sectional view showing a step of the method for manufacturing the electronic device according to the first embodiment, and corresponds to the cross section in FIG. 8.

FIG. 19 is a cross-sectional view showing a step of the method for manufacturing the electronic device according to the first embodiment, and corresponds to the cross section in FIG. 8.

FIG. 20 is a cross-sectional view showing an electronic device according to a first variation of the first embodiment, and corresponds to the cross section in FIG. 8.

FIG. 21 is a cross-sectional view showing an electronic device according to a second variation of the first embodiment, and corresponds to the cross section in FIG. 8.

FIG. 22 is a partially enlarged cross-sectional view showing an electronic device according to a second embodiment, and corresponds to FIG. 9.

FIG. 23 is a plan view showing another configuration of the electronic device according to the present disclosure, with the sealing resin indicated by imaginary lines.

### DETAILED DESCRIPTION OF EMBODIMENTS

The following describes preferred embodiments of an electronic device according to the present disclosure with reference to the drawings. In the following description, identical or similar elements are denoted by the same reference numerals and redundant descriptions of such elements are omitted. The terms such as "first", "second" and "third" in the present disclosure are used merely as labels and not intended to impose orders on the elements accompanied with these terms.

In the present disclosure, the phrases "an object A is formed in an object B" and "an object A is formed on an object B" include, unless otherwise specified, "an object A is formed directly in/on an object B" and "an object A is formed in/on an object B with another object interposed between the object A and the object B". Similarly, the phrases "an object A is disposed in an object B" and "an object A is disposed on an object B" include, unless otherwise specified, "an object A is disposed directly in/on an object B" and "an object A is disposed in/on an object B with another object interposed between the object A and the object B". Similarly, the phrase "an object A is located on an object B" includes, unless otherwise specified, "an object A is located on an object B in contact with the object B" and "an object A is located on an object B with another object interposed between the object A and the object B". The phrase "an object A overlaps with an object B as viewed in a certain direction" includes, unless otherwise specified, "an object A overlaps with the entirety of an object B" and "an object A overlaps with a portion of an object B". The phrase "an object A (or the material thereof) contains a material C" includes "an object A (or the material thereof) is made of a material C" and "an object A (or the material thereof) is mainly composed of a material C". The phrase "a surface A faces (a first side or a second side) in a direction B", unless otherwise specified, is not limited to the case where the angle of the surface A with respect to the direction B is 90°, but also includes the case where the surface A is inclined to the direction B. The phrase "a surface A is perpendicular to a surface B (a direction B)" is not limited to the case where the angle of the surface A with respect to the surface B (the direction B) is exactly 90°, but also includes the case where the angle is approximately 90° (e.g., within a range of tolerance resulting from manufacturing variations).

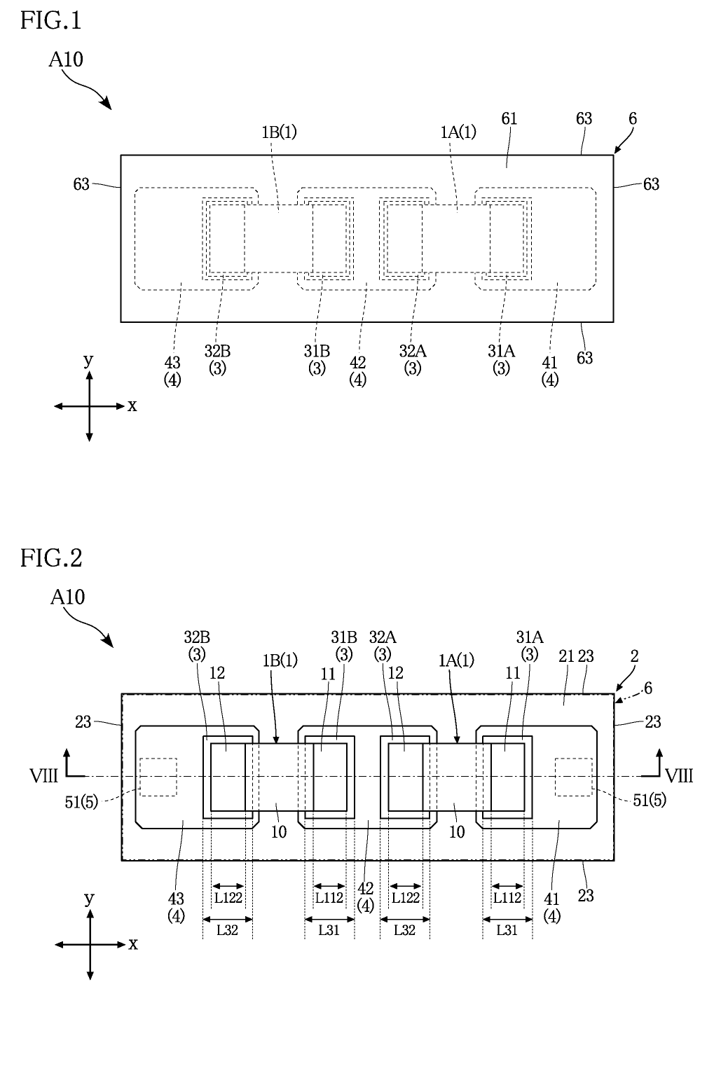

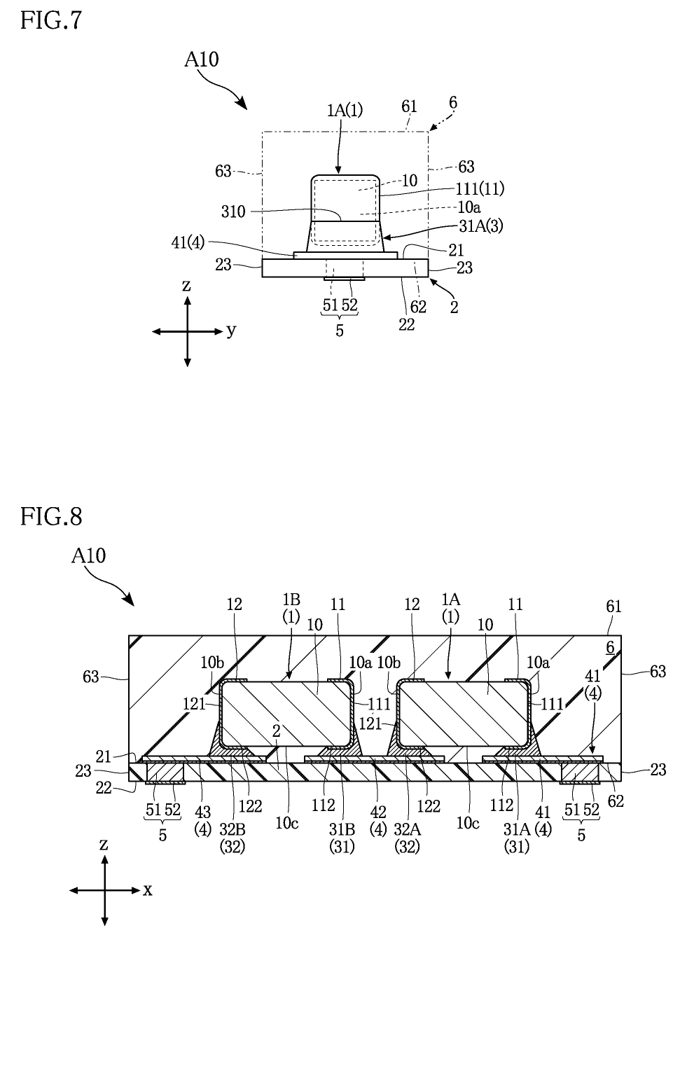

FIGS. 1 to 10 show an electronic device A10 according to a first embodiment. The electronic device A10 includes a plurality of electronic components 1, a support member 2, a plurality of conductive bonding members 3, a wiring layer 4, a plurality of terminals 5, and a sealing resin 6. The electronic device A10 is surface-mountable onto the circuit board of an electronic apparatus (such as an electrical product or an electric vehicle). The electronic device A10 is of a leadless package type. The electronic device A10 has a rectangular shape in plan view, for example.

For convenience, the thickness direction of the electronic device A10 is referred to as "thickness direction z". In the description below, a first side in the thickness direction z may be referred to as "upward", and a second side as "downward". The terms such as "top", "bottom", "upward", "downward", "upper surface", and "lower surface" are used to indicate the relative positions of elements and components in the thickness direction z and do not necessarily define the relationship with respect to the direction of gravity. "Plan view" refers to the view seen in the thickness direction z. A direction perpendicular to the thickness direction z is referred to as "first direction x". The direction perpendicular to the thickness direction z and the first direction x is referred to as "second direction y".

As shown in FIGS. 2, and FIGS. 5 to 10, the electronic components 1 are supported by the support member 2. The electronic components 1 are surface-mount devices (SMD). Each of the electronic components 1 may be one of a resistor, a capacitor, an inductor, or a diode. The electronic components 1 are the functional elements of the electronic device A10. In the electronic device A10, the electronic components 1 include two electronic components 1A and 1B. In other words, the electronic device A10 includes two electronic components 1A and 1B. In the electronic device A10, the number of electronic components 1 is not limited to two, and may be one or at least three. The thickness (dimension in the thickness direction z) of each of the electronic components 1 (the two electronic components 1A and 1B) is at least 200 μm and at most 1500 μm, for example.

As shown in FIGS. 2, 5, and 8, each of the electronic components 1 (the two electronic components 1A and 1B) includes a body 10 and a pair of terminals 11 and 12. Unless otherwise specified, the following description of the body 10 and the pair of terminals 11 and 12 applies to each of the electronic components 1 (the electronic components 1A and 1B).

The body 10 forms the functional core of an electronic component 1, and operates as a resistor, a capacitor, an inductor, or a diode by energization of the electronic component 1. As shown in FIG. 2, in the illustrated example, the body 10 has a rectangular shape elongated in the first direction x in plan view.

As shown in FIGS. 8 to 10, the body 10 has a pair of side surfaces 10a and 10b, and a bottom surface 10c. The pair of side surfaces 10a and 10b are spaced apart and face away from each other in the longitudinal direction (the first direction x in the illustrated example) of each electronic component 1. The bottom surface 10c is connected to each of the pair of side surfaces 10a and 10b, and is flanked by them. The bottom surface 10c faces downward in the thickness direction z to face the support member 2. The body 10 includes an upper surface facing upward in the thickness direction z, a side surface facing a first side in the second direction y, and a side surface facing a second side in the second direction y, in addition to the pair of side surfaces 10a and 10b and the bottom surface 10c.

As shown in FIGS. 2, 5, and 8 to 10, the pair of terminals 11 and 12 are disposed on the respective sides in the first direction x. In each of the electronic components 1 (the electronic components 1A and 1B), the terminal 11 is disposed at the end on a first side in the first direction x, and the terminal 12 is disposed at the end on a second side in the first direction x.

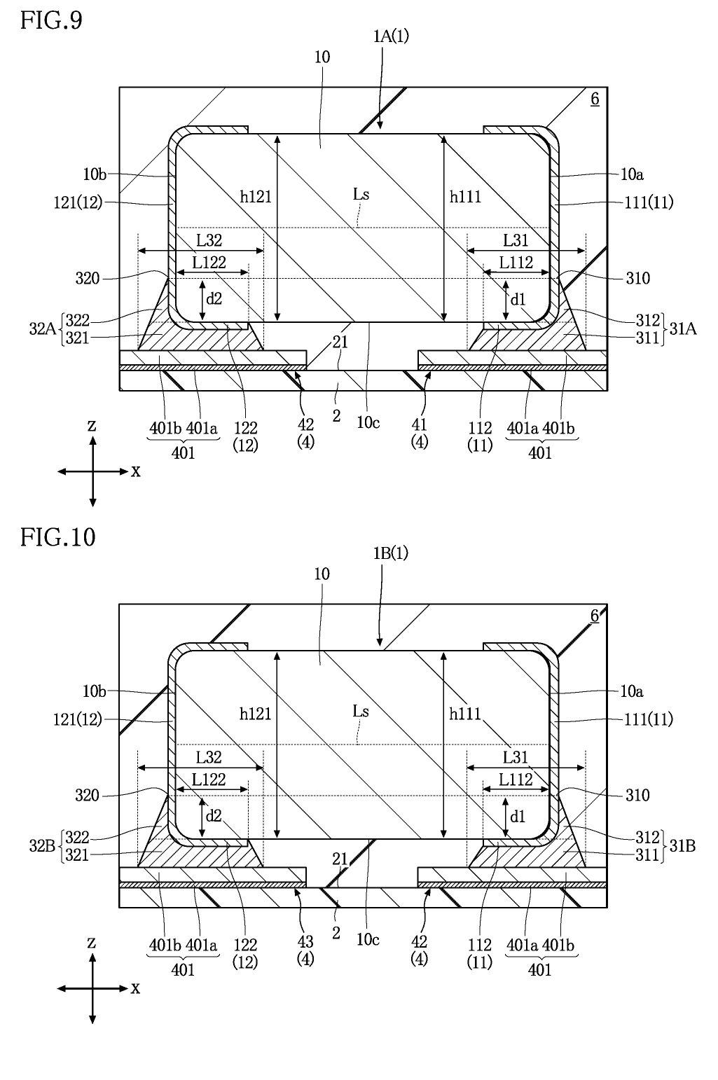

As shown in FIGS. 9 and 10, the terminal 11 includes a side electrode 111 and a bottom electrode 112. The side electrode 111 covers the entirety of the side surface 10a. Thus, the side electrode 111 extends from the edge of the side surface 10a on the upper side (first side) in the thickness direction z to the edge of the side surface 10a on the lower side (second side) in the thickness direction z. The bottom electrode 112 covers a part of the bottom surface 10c. The bottom electrode 112 covers the area of the bottom surface 10c near the edge thereof on the first side in the first direction x. The bottom electrode 112 is connected to the side electrode 111. A dimension L112 of the bottom electrode 112 in the first direction x (i.e., the dimension of the terminal 11 in the first direction x) is at least 50 μm and at most 800 μm, for example. The terminal 11 includes a portion covering a part of the upper surface of the body 10, a portion covering a part of the side surface of the body 10 facing the first side in the second direction y, and a portion covering a part of the side surface of the body 10 facing the second side in the second direction y, in addition to the side electrode 111 and the bottom electrode 112. In the present disclosure, the boundary between the side electrode 111 and the bottom electrode 112 is defined with reference to the bottom surface 10c, where the upper side in the thickness direction z corresponds to the side electrode 111 and the lower side in the thickness direction z corresponds to the bottom electrode 112.

As shown in FIGS. 9 and 10, the terminal 12 includes a side electrode 121 and a bottom electrode 122. The side electrode 121 covers the entirety of the side surface 10b. Thus, the side electrode 121 extends from the edge of the side surface 10b on the upper side (first side) in the thickness direction z to the edge of the side surface 10b on the lower side (second side) in the thickness direction z. The bottom electrode 122 covers a part of the bottom surface 10c. The bottom electrode 122 covers the area of the bottom surface 10c near the edge thereof on the second side in the first direction x. The bottom electrode 122 is connected to the side electrode 121. A dimension L122 of the bottom electrode 122 in the first direction x (i.e., the dimension of the terminal 12 in the first direction x) is at least 50 μm and at most 800 μm, for example. The terminal 12 includes a portion covering a part of the upper surface of the body 10, a portion covering a part of the side surface of the body 10 facing the first side in the second direction y, and a portion covering a part of the side surface of the body 10 facing the second side in the second direction y, in addition to the side electrode 121 and the bottom electrode 122. In the present disclosure, the boundary between the side electrode 121 and the bottom electrode 122 is defined with reference to the bottom surface 10c, where the upper side in the thickness direction z corresponds to the side electrode 121 and the lower side in the thickness direction z corresponds to the bottom electrode 122.

As shown in FIGS. 2 and 5 to 10, the support member 2 supports the electronic components 1. The support member 2 contains insulating resin, for example. The insulating resin is the same as the sealing resin 6 (epoxy resin as described below) in one example, but may be different from the sealing resin 6 in another example. The support member 2 may contain a filler, such as silica, mixed with the insulating resin. Instead of insulating resin, the support member 2 may contain a single-crystal intrinsic semiconductor (e.g., silicon (Si)), glass, or ceramics. As shown in FIGS. 2 to 4, the support member 2 has a rectangular shape in plan view. The thickness (the dimension in the thickness direction z) of the support member 2 is not particularly limited, but may be at least 30 μm and at most 300 μm. The support member 2 has a mounting surface 21, a reverse surface 22, and a plurality of side surfaces 23.

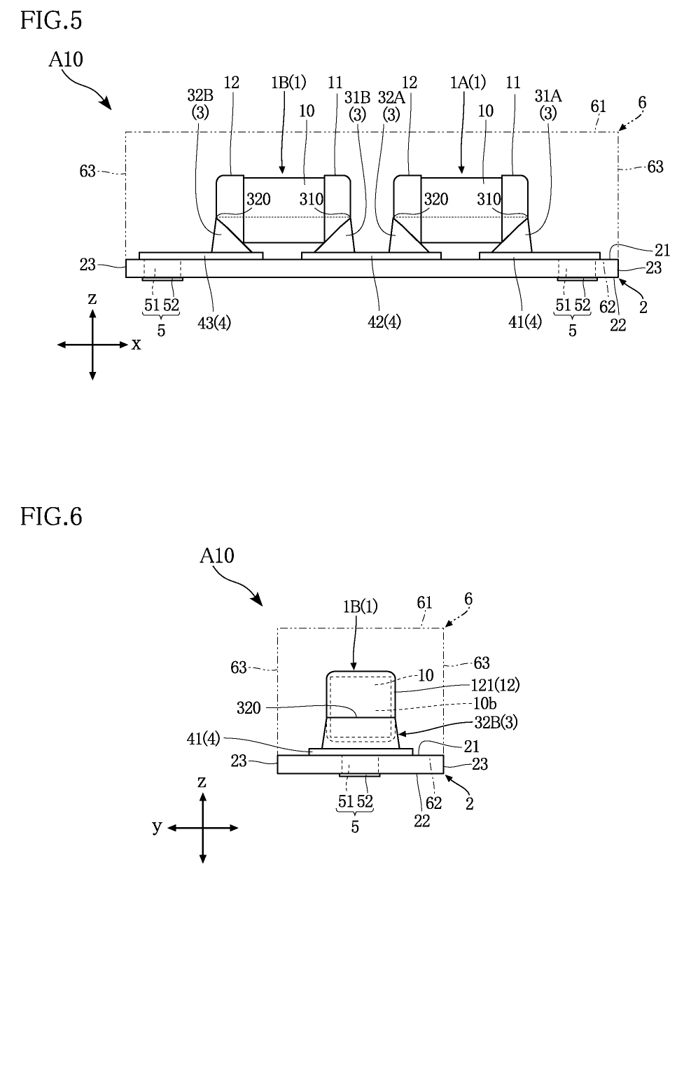

As shown in FIGS. 5 to 8, the mounting surface 21 and the reverse surface 22 are spaced apart from each other in the thickness direction z. The mounting surface 21 and the reverse surface 22 face away from each other. The mounting surface 21 is the upper surface of the support member 2, and the reverse surface 22 is the lower surface of the support member 2. The mounting surface 21 faces the electronic components 1. The reverse surface 22 faces a circuit board when the electronic device A10 is mounted on the circuit board. In the present embodiment, the mounting surface 21 is covered with the sealing resin 6, and the reverse surface 22 is exposed from the sealing resin 6. As shown in FIGS. 5 to 8, the side surfaces 23 are located between the mounting surface 21 and the reverse surface 22. The upper end of each side surface 23 in the thickness direction z is connected to the mounting surface 21, and the lower end of each side surface 23 in the thickness direction z is connected to the reverse surface 22. Each side surface 23 is flat and perpendicular to the mounting surface 21 and the reverse surface 22. As shown in FIGS. 2 to 4, the side surfaces 23 include one facing the first side in the first direction x, one facing the second side in the first direction x, one facing the first side in the second direction y, and one facing the second side in the second direction y.

The dimensional relationship between the thickness (the dimension in the thickness direction z) of the support member 2 and the thickness (the dimension in the thickness direction z) of each electronic component 1 is not particularly limited, but it is preferable that the thickness of the support member 2 be at least 1/20 and at most 1/5 of the thickness of each electronic component 1. For example, when the thickness of each electronic component 1 is 500 μm, the thickness of the support member 2 is preferably at least 25 μm and at most 100 μm.

The wiring layer 4 is a conductor disposed in the electronic device A10. The wiring layer 4 electrically connects the electronic components 1 and the terminals 5. As shown in FIG. 5, the wiring layer 4 is formed on the mounting surface 21 of the support member 2.

As shown in FIGS. 2, 3, 5, and 8, the wiring layer 4 includes a plurality of wiring sections 41, 42, and 43. The wiring sections 41, 42, 43 are spaced apart from each other. The wiring sections 41, 42, and 43 are disposed in the first direction x. In the illustrated example, the wiring section 42 is located between the wiring section 41 and the wiring section 43 in the first direction x. The wiring section 41 is offset to the first side in the first direction x relative to the wiring section 42.

As shown in FIG. 8, the terminal 11 of the electronic component 1A is bonded to the wiring section 41. Thus, the wiring section 41 is electrically connected to the terminal 11 of the electronic component 1A. The wiring section 41 is electrically connected to one of the terminals 5. As shown in FIG. 8, the terminal 12 of the electronic component 1A and the terminal 11 of the electronic component 1B are bonded to the wiring section 42. Thus, the wiring section 42 is electrically connected to the terminal 12 of the electronic component 1A and the terminal 11 of the electronic component 1B. As shown in FIG. 8, the terminal 12 of the electronic component 1B is bonded to the wiring section 43. The wiring section 43 is electrically connected to one of the terminals 5. Thus, the wiring section 43 is electrically connected to the terminal 12 of the electronic component 1B. As shown in FIGS. 2, 5, and 8, the electronic component 1A is disposed across the two wiring sections 41 and 42 in plan view. The electronic component 1B is disposed across the two wiring sections 42 and 43 in plan view.

As shown in FIGS. 9 and 10, the wiring layer 4 (each of the wiring sections 41, 42, and 43) includes a conductive layer 401. The conductive layer 401 electrically connects two portions spaced apart from each other, and forms a conductive path between these portions.

As shown in FIGS. 9 and 10, the conductive layer 401 includes a seed layer 401a and a metal layer 401b. The seed layer 401a is formed on the mounting surface 21. The seed layer 401a contains titanium (Ti), for example. The metal layer 401b is stacked on the seed layer 401a. The metal layer 401b contains copper (Cu), for example. Unlike this configuration, the conductive layer 401 may be a single layer made of a conductor. The thickness (the dimension in the thickness direction z) of the conductive layer 401 is not particularly limited, but may be at least 10 μm and at most 100 μm.

Each of the conductive bonding members 3 bonds the wiring layer 4 and one of the electronic components 1. The electronic components 1 are electrically connected to the wiring layer 4 via the conductive bonding members 3. Each of the conductive bonding members 3 is made of a conductive bonding material. For example, the conductive bonding members 3 are made of solder. The solder contains an alloy containing tin (Sn) (e.g., Sn-silver (Ag) alloy), and also contains flux. Note that the composition of each conductive bonding member 3 is not limited to this example. Each of the conductive bonding members 3 may be sintered metal or conductive paste instead of solder. In the present embodiment, as shown in FIGS. 2, 3, 5, and FIG. 8, the conductive bonding members 3 include a pair of conductive bonding members 31A and 32A and a pair of conductive bonding members 31B and 32B.

As shown in FIGS. 2 and 8, the pair of conductive bonding members 31A and 32A bond the electronic component 1A to the wiring layer 4. The conductive bonding member 31A bonds the terminal 11 of the electronic component 1A to the wiring section 41. The conductive bonding member 32A bonds the terminal 12 of the electronic component 1A to the wiring section 42. In the illustrated example, each of the conductive bonding members 31A and 32A has a conical shape, for example, and the area of the cross section of each of the conductive bonding members 31A and 32A, which is perpendicular to the thickness direction z, increases as proceeding downward in the thickness direction z.

As shown in FIGS. 2 and 8, the pair of conductive bonding members 31B and 32B bond the electronic component 1B to the wiring layer 4. The conductive bonding member 31B bonds the terminal 11 of the electronic component 1B to the wiring section 42. The conductive bonding member 32B bonds the terminal 12 of the electronic component 1B to the wiring section 43. In the illustrated example, each of the conductive bonding members 31B and 32B has a conical shape, for example, and the area of the cross section of each of the conductive bonding members 31B and 32B, which is perpendicular to the thickness direction z, increases as proceeding downward in the thickness direction z.

As shown in FIGS. 9 and 10, each of the conductive bonding members 31A and 31B includes an intervening portion 311 and a fillet 312. In each of the conductive bonding members 31A and 31B, the intervening portion 311 and the fillet 312 are continuous and formed integrally. The intervening portion 311 of the conductive bonding member 31A is located between the electronic component 1A and the wiring section 41 in the thickness direction z. The intervening portion 311 of the conductive bonding member 31B is located between the electronic component 1B and the wiring section 42 in the thickness direction z. The thickness (the dimension in the thickness direction z) of the intervening portion 311 of each of the conductive bonding members 31A and 31B is not particularly limited, but may be at least 5 μm and at most 50 μm. In each of the conductive bonding members 31A and 31B, the fillet 312 covers a part of the side electrode 111 of a corresponding one of the electronic components 1A and 1B. In each of the conductive bonding members 31A and 31B, the fillet 312 is in contact with the side electrode 111 of a corresponding one of the electronic components 1A and 1B. Although the side surface of each fillet 312 is flatly inclined to the x-y plane perpendicular to the thickness direction z, it may be curved outward or inward.

As shown in FIGS. 5, 9, and 10, each of the conductive bonding members 31A and 31B has a top 310. In the present embodiment, the fillet 312 of each of the conductive bonding members 31A and 31B has a top 310. Unless otherwise specified, the following description of the top 310 applies to each of the conductive bonding members 31A and 31B.

In each of the conductive bonding members 31A and 31B, the top 310 is located at the uppermost position in the thickness direction z. A distance d1 (see FIGS. 9 and 10) between the top 310 and the bottom surface 10c in the thickness direction z is at least zero and at most 1/2 (preferably at least zero and at most 1/4) of a dimension h111 of the side electrode 111 in the thickness direction z. In other words, the height of each of the conductive bonding members 31A and 31B that climb up along the side electrode 111 extends from the lower end of the side electrode 111 up to a middle Ls (see FIGS. 9 and 10) of the side electrode 111 in the thickness direction z. In the present embodiment, each of the conductive bonding members 31A and 31B includes a fillet 312. Accordingly, the distance d1 is greater than zero and at most 1/2 (preferably at most 1/4) of the dimension h111 of the side electrode 111 in the thickness direction z. When each of the conductive bonding members 31A and 31B does not include a fillet 312, the distance d1 is zero times the dimension h111 of the corresponding side electrode 111 in the thickness direction z.

The dimensional relationship between a dimension L31 (see FIGS. 2, 9, and FIG. 10) of each of the conductive bonding members 31A and 31B in the first direction x and the dimension L112 (see FIGS. 2, 9, and FIG. 10) of the bottom electrode 112 of each of the electronic components 1A and 1B in the first direction x is not particularly limited; however, it is preferable that the dimension L31 of each of the conductive bonding members 31A and 31B in the first direction x be at least 1.0 times and at most 1.5 times the dimension L112 of the bottom electrode 112 in the first direction x.

As will be understood from FIGS. 9 and 10, each of the conductive bonding members 32A and 32B includes an intervening portion 321 and a fillet 322. In each of the conductive bonding members 32A and 32B, the intervening portion 321 and the fillet 322 are continuous and formed integrally. The intervening portion 321 of the conductive bonding member 32A is located between the electronic component 1A and the wiring section 42 in the thickness direction z. The intervening portion 321 of the conductive bonding member 32B is located between the electronic component 1B and the wiring section 43 in the thickness direction z. The thickness (the dimension in the thickness direction z) of the intervening portion 321 of each of the conductive bonding members 32A and 32B is not particularly limited, but may be at least 5 μm and at most 50 μm. In each of the conductive bonding members 32A and 32B, the fillet 322 covers a part of the side electrode 121 of a corresponding one of the electronic components 1A and 1B. In each of the conductive bonding members 32A and 32B, the fillet 322 is in contact with the side electrode 121 of a corresponding one of the electronic components 1A and 1B. Although the side surface of each fillet 322 is flatly inclined to the x-y plane perpendicular to the thickness direction z, it may be curved outward or inward.

As shown in FIGS. 5, 9, and FIG. 10, each of the conductive bonding members 32A and 32B has a top 320. In the present embodiment, the fillet 322 of each of the conductive bonding members 32A and 32B has a top 320. Unless otherwise specified, the following description of the top 320 applies to each of the conductive bonding members 32A and 32B.

In each of the conductive bonding members 32A and 32B, the top 320 is located at the uppermost position in the thickness direction z. A distance d2 (see FIGS. 9 and 10) between the top 320 and the bottom surface 10c in the thickness direction z is at least zero and at most 1/2 (preferably at least zero and at most 1/4) of a dimension h121 of the side electrode 121 in the thickness direction z. In other words, the height of each of the conductive bonding members 32A and 32B that climb up along the side electrode 121 extends from the lower end of the side electrode 121 up to the middle Ls (see FIGS. 9 and 10) of the side electrode 121 in the thickness direction z. In the present embodiment, each of the conductive bonding members 32A and 32B includes a fillet 322. Accordingly, the distance d2 is greater than zero and at most 1/2 (preferably at most 1/4) of the dimension h121 of the side electrode 121 in the thickness direction z. In other words, when each of the conductive bonding members 32A and 32B does not include a fillet 322, the distance d2 is zero times the dimension h121 of the corresponding side electrode 121 in the thickness direction z. As will be understood from FIGS. 5, 9, and FIG. 10, the top 320 in the present embodiment is located at the same position as the top 310 as viewed in the first direction x. In other words, the height of each of the conductive bonding members 32A and 32B that climb up along the side electrode 121 is the same as the height of each of the conductive bonding members 31A and 31B that climb up along the side electrode 111.

The dimensional relationship between a dimension L32 (see FIGS. 2, 9, and FIG. 10) of each of the conductive bonding members 32A and 32B in the first direction x and the dimension L122 (see FIGS. 2, 9, and FIG. 10) of the bottom electrode 122 of each of the electronic components 1A and 1B in the first direction x is not particularly limited; however, it is preferable that the dimension L32 of each of the conductive bonding members 32A and 32B in the first direction x be at least 1.0 times and at most 1.5 times the dimension L122 of the bottom electrode 122 in the first direction x.

The terminals 5 are conductors electrically connected to the wiring layer 4 and exposed to the outside of the electronic device A10. The terminals 5 are used when the electronic device A10 is mounted onto a circuit board. As shown in FIGS. 5 to 8, the terminals 5 penetrate through the support member 2 in the thickness direction z. In the illustrated example, the electronic device A10 includes two terminals 5. As shown in FIG. 8, one of the two terminals 5 is in contact with the wiring section 41, and the other of the two terminals 5 is in contact with the wiring section 43. Unlike this example, the electronic device A10 may further include a terminal 5 that is in contact with the wiring section 42.

As shown in FIGS. 5 to 8, each of the terminals 5 includes a columnar portion 51 and an external electrode portion 52. Unless otherwise specified, the description of the columnar portion 51 and the external electrode portion 52 given below applies to each of the terminals 5.

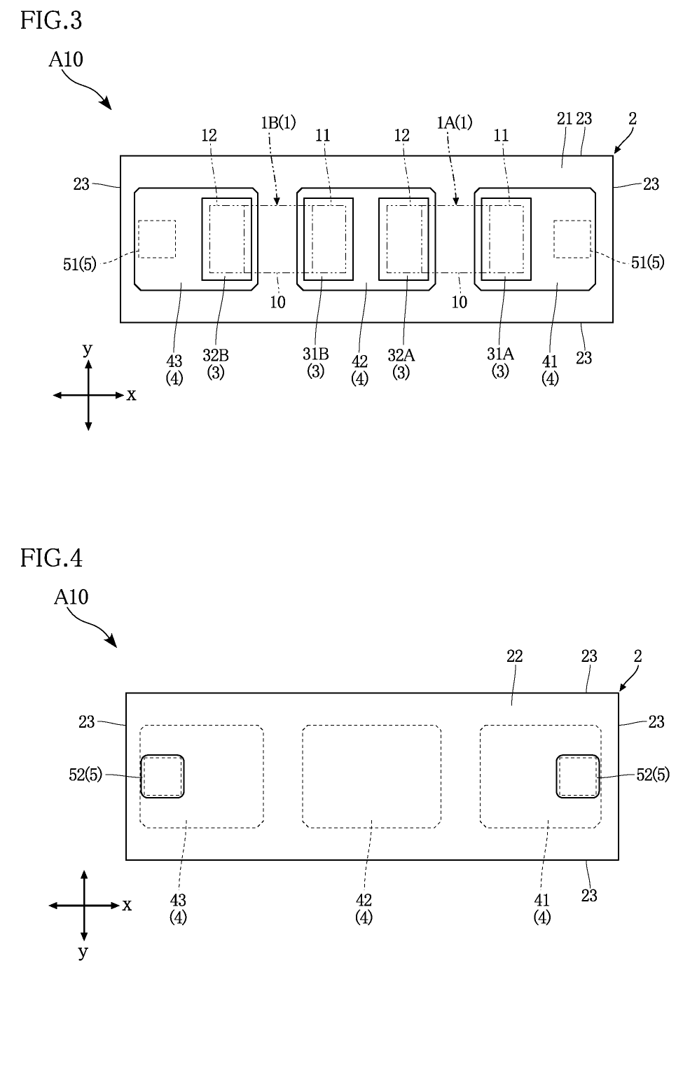

As shown in FIG. 8, the columnar portion 51 penetrates through the support member 2 in the thickness direction z. The columnar portion 51 contains a metal material, for example. The metal material is not particularly limited, but may be Cu. The shape of the columnar portion 51 in plan view is not particularly limited, but is a rectangle in the example shown in FIGS. 2 and 3. The upper surface (the surface facing upward in the thickness direction z) of the columnar portion 51 is flush with the mounting surface 21 of the support member 2, for example. The upper surface of the columnar portion 51 is in contact with the wiring layer 4. The terminals 5 may include one having a columnar portion 51 whose upper surface is not in contact with the wiring layer 4. Such a terminal 5 serves as a dummy terminal. The lower surface (the surface facing downward in the thickness direction z) of the columnar portion 51 is exposed from the support member 2. The lower surface of the columnar portion 51 is flush with the reverse surface 22 of the support member 2, for example. In the present embodiment, the columnar portion 51 of each terminal 5 has side surfaces (each facing in the first direction x or in the second direction y) covered with the support member 2. Unlike this example, the columnar portions 51 of some of the terminals 5 may have side surfaces exposed to the outside.

As shown in FIG. 8, the external electrode portion 52 is in contact with a part of the columnar portion 51 that is exposed from the reverse surface 22 of the support member 2. As shown in FIGS. 5 to 8, the external electrode portion 52 protrudes from the reverse surface 22. The external electrode portion 52 is formed by electroless plating. In one example, the external electrode portion 52 is made up of a plurality of metal layers stacked in the order of an Ni layer, a palladium (Pd) layer, and a gold (Au) layer, starting from the side in contact with the columnar portion 51. In another example, the external electrode portion 52 may be made up of a plurality of metal layers stacked in the order of an Ni layer and an Au layer or a plurality of metal layers stacked in the order of a Cu layer, an Ag layer, and an Sn layer, starting from the side in contact with the columnar portion 51. The material and formation method of the external electrode portion 52 are not limited to these examples.

The sealing resin 6 is made of a synthetic resin mainly containing black epoxy resin, for example. The epoxy resin in the sealing resin 6 may be mixed with a filler such as silica. As shown in FIGS. 1, 2, and 5 to 8, the sealing resin 6 covers the electronic components 1 (the two electronic components 1A and 1B). As shown in FIGS. 5 to 8, the sealing resin 6 covers the conductive bonding members 3 (the conductive bonding members 31A, 31B, 32A, and 32B), the wiring layer 4, and a part of the support member 2. The sealing resin 6 is formed on the mounting surface 21. The sealing resin 6 has a rectangular shape in plan view. The thickness (the dimension in the thickness direction z) of the sealing resin 6 is not particularly limited, but may be at least 300 μm and at most 1200 μm. As shown in FIGS. 1 and 5 to 8, the sealing resin 6 has a resin obverse surface 61, a resin reverse surface 62, and a plurality of resin side surfaces 63.

As shown in FIGS. 5 to 8, the resin obverse surface 61 and the resin reverse surface 62 are spaced apart from each other in the thickness direction z. The resin obverse surface 61 and the resin reverse surface 62 face away from each other in the thickness direction z. The resin obverse surface 61 faces the same side as the mounting surface 21 in the thickness direction z, and the resin reverse surface 62 faces the same side as the reverse surface 22 in the thickness direction z. The resin reverse surface 62 is in contact with the mounting surface 21. The resin reverse surface 62 has recesses and protrusions corresponding to the shape of the wiring layer 4. As shown in FIGS. 1, 2, and 5 to 8, the resin side surfaces 63 are located between the resin obverse surface 61 and the resin reverse surface 62 in the thickness direction z, and are connected to these surfaces. The resin side surfaces 63 are flush with the respective side surfaces 23.

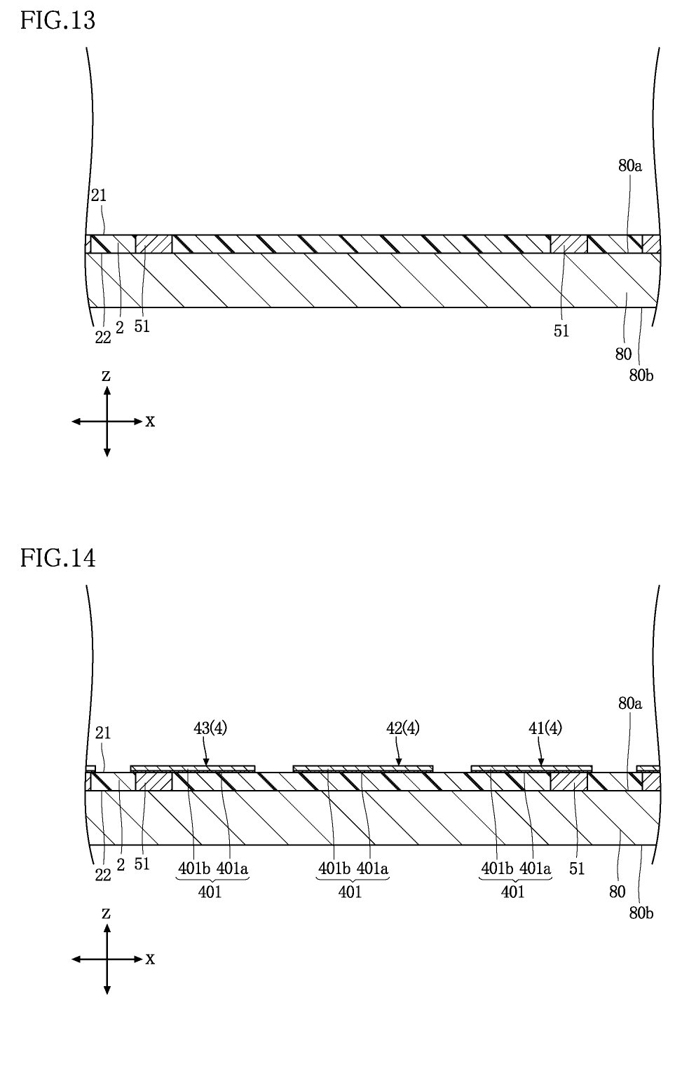

The following describes an example of a method for manufacturing the electronic device A10, with reference to FIGS. 11 to 19. FIGS. 11 to 19 are cross-sectional views each showing a step of the method for manufacturing the electronic device A10. These cross-sectional views are taken along the same line as in FIG. 8.

First, as shown in FIG. 11, a support substrate 80 is prepared, and a plurality of columnar portions 51 are formed on the support substrate 80. The support substrate 80 contains a single-crystal intrinsic semiconductor material, for example. The semiconductor material is Si, for example. In the step of preparing the support substrate 80, a silicon wafer, which serves as the support substrate 80, may be prepared. The support substrate 80 has a substrate obverse surface 80a and a substrate reverse surface 80b that face away from each other in the thickness direction z. The columnar portions 51 may be formed through the following steps. First, a seed layer is formed on the substrate obverse surface 80a. The seed layer may be formed by sputtering. Next, a resist is patterned on the seed layer to form the columnar portions 51 by electroplating. Then, the resist and unnecessary parts of the seed layer are removed. Through the steps described above, the columnar portions 51 are formed on the substrate obverse surface 80a of the support substrate 80.

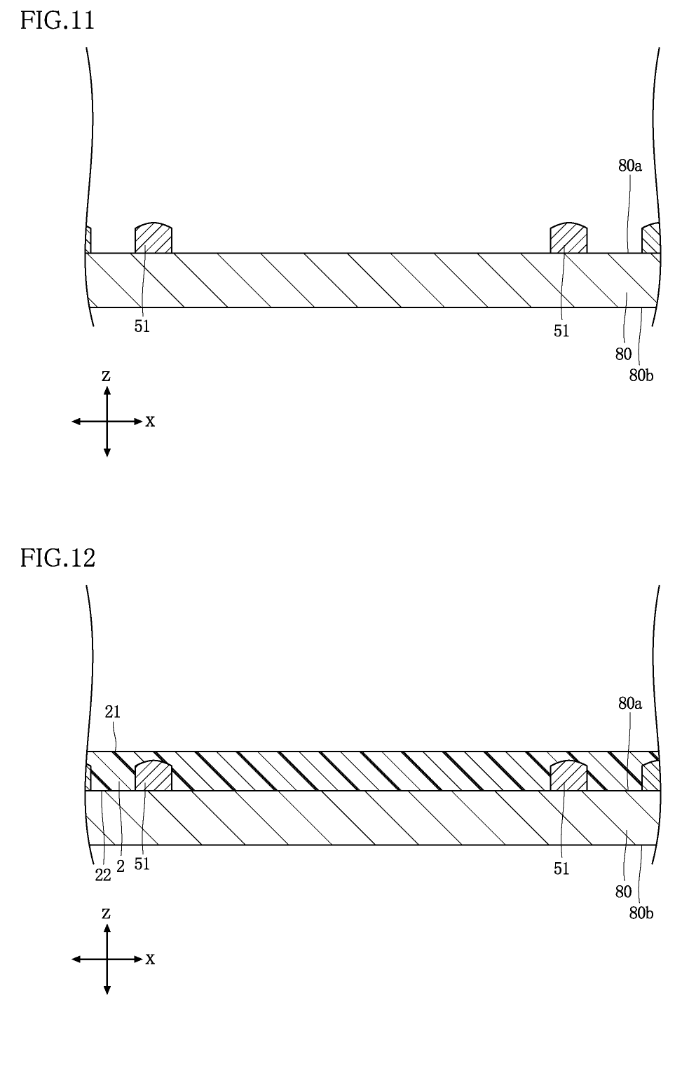

Next, as shown in FIG. 12, a support member 2 (resin layer) is formed on the substrate obverse surface 80a of the support substrate 80 to cover the columnar portions 51. The support member 2 (resin layer) is formed by molding, for example. The support member 2 (resin layer) is made of a synthetic resin mainly containing black epoxy resin, for example. The support member 2 (resin layer) may be made of another insulating resin instead of the synthetic resin. The support member 2 (resin layer) has a mounting surface 21 and a reverse surface 22 that face away from each other in the thickness direction z. The mounting surface 21 faces in the same direction as the substrate obverse surface 80a, and the reverse surface 22 faces the substrate obverse surface 80a.

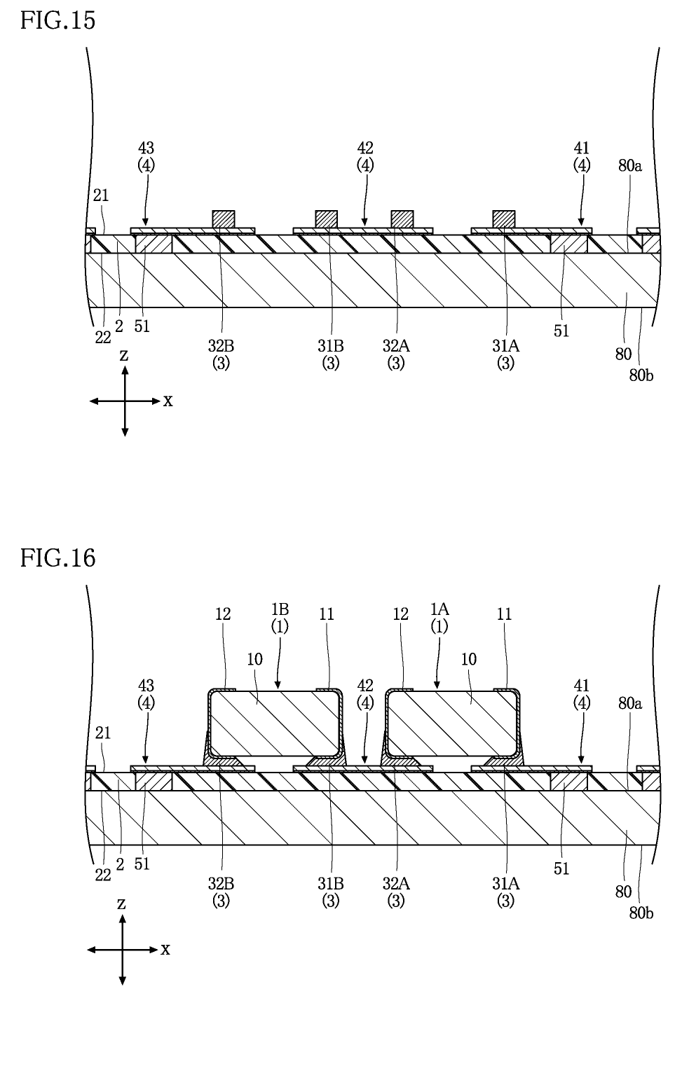

Next, as shown in FIG. 15, the support member 2 (resin layer) is ground. The grinding of the support member 2 is performed from the mounting surface 21 toward the lower side in the thickness direction z until the columnar portions 51 are exposed from the mounting surface 21. A method for the grinding is not particularly limited. A method other than grinding can be selected to reduce the height of the support member 2.

Next, as shown in FIG. 14, the wiring layer 4 is formed. The wiring layer 4 is formed through the following steps. First, a seed layer 401a is formed on the mounting surface 21 and the columnar portions 51. The seed layer 401a may be formed by sputtering. For example, a Ti layer and a Cu layer are stacked in sequence to form the seed layer 401a. Then, a resist is patterned on the seed layer 401a, and a metal layer 401b is formed by electroplating. For example, the metal layer 401b contains Cu. Subsequently, the resist and unnecessary parts of the seed layer 401a (i.e., parts of the seed layer 401a exposed from the metal layer 401b) are removed. Through these steps, the wiring layer 4 (each of the wiring sections 41, 42, and 43) is formed.

Next, as shown in FIG. 15, a plurality of conductive bonding members 3 (conductive bonding members 31A, 31B, 32A, and 32B) are formed. In the step of forming the conductive bonding members 3, solder paste serving as each of the conductive bonding members 3 is formed on the wiring layer 4 by screen printing.

Next, as shown in FIG. 16, a plurality of electronic components 1 are mounted and then bonded. As shown in FIG. 16, in the step of mounting, the electronic components 1 are placed such that the terminal 11 of the electronic component 1A corresponds to the conductive bonding member 31A, the terminal 12 of the electronic component 1A corresponds to the conductive bonding member 32A, the terminal 11 of the electronic component 1B corresponds to the conductive bonding member 31B, and the terminal 12 of the electronic component 1B corresponds to the conductive bonding member 32B. Next, reflow is performed in the state where the electronic components 1 (the electronic components 1A and 1B) are placed. Heat from the reflow causes the conductive bonding members 31A, 31B, 32A, and 32B to melt, and the conductive bonding members 31A, 31B, 32A, and 32B become more fluid than when they are in the form of paste. Next, the melted conductive bonding members 31A, 31B, 32A, and 32B are cooled. As a result, the conductive bonding members 31A, 31B, 32A, and 32B solidify to bond the electronic components 1 (the electronic components 1A and 1B). After solidification, each of the conductive bonding members 31A and 31B includes an intervening portion 311 and a fillet 312. After solidification, each of the conductive bonding members 32A and 32B includes an intervening portion 321 and a fillet 322.

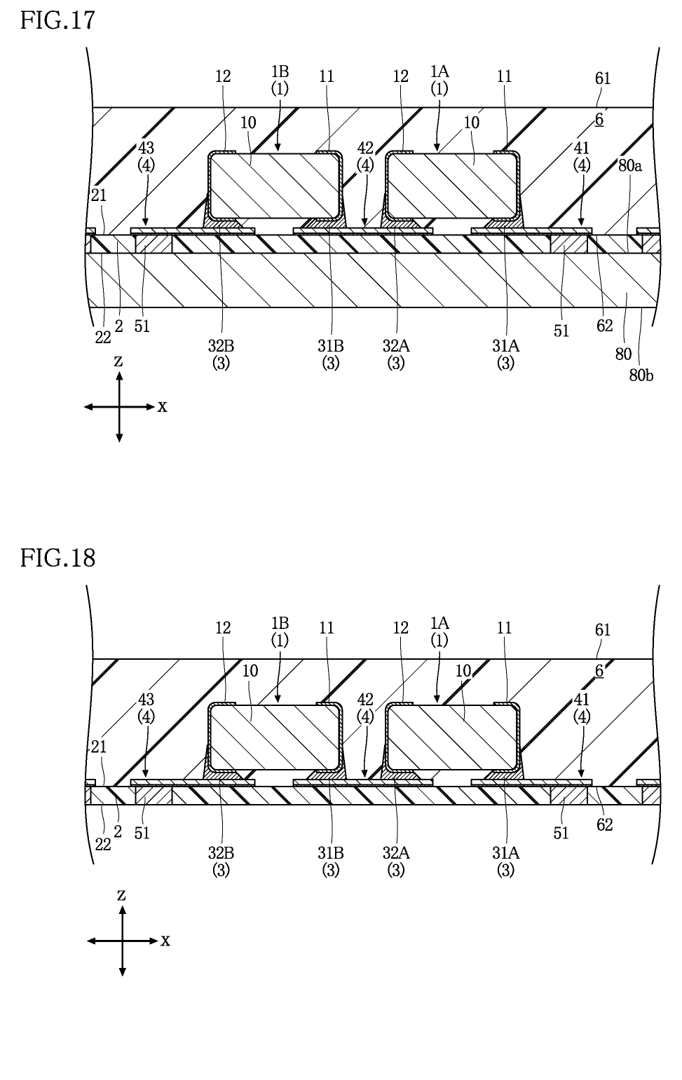

Next, as shown in FIG. 17, a sealing resin 6 is formed. The sealing resin 6 is formed over the support member 2 to cover the electronic components 1 and the wiring layer 4. The sealing resin 6 is formed by molding, for example. The sealing resin 6 is made of a synthetic resin mainly containing black epoxy resin, for example. The sealing resin 6 may be made of another insulating resin material instead of the synthetic resin. The sealing resin 6 has a resin obverse surface 61 facing a first side in the thickness direction z. In order to reduce the height of the sealing resin 6, the sealing resin 6 may be ground downward in the thickness direction z from the resin obverse surface 61 to the extent that does not expose the electronic components 1.

Next, as shown in FIG. 18, the support substrate 80 is removed. In the step of removing the support substrate 80, for example, the support substrate 80 may be ground from the substrate reverse surface 80b side in the state shown in FIG. 17. In this grinding step, the support substrate 80 is ground from the substrate reverse surface 80b side. In the illustrated example, the grinding is performed continuously even after the support substrate 80 is removed so as to reduce the height of each of the support member 2 and the columnar portions 51. This height reduction may be omitted.

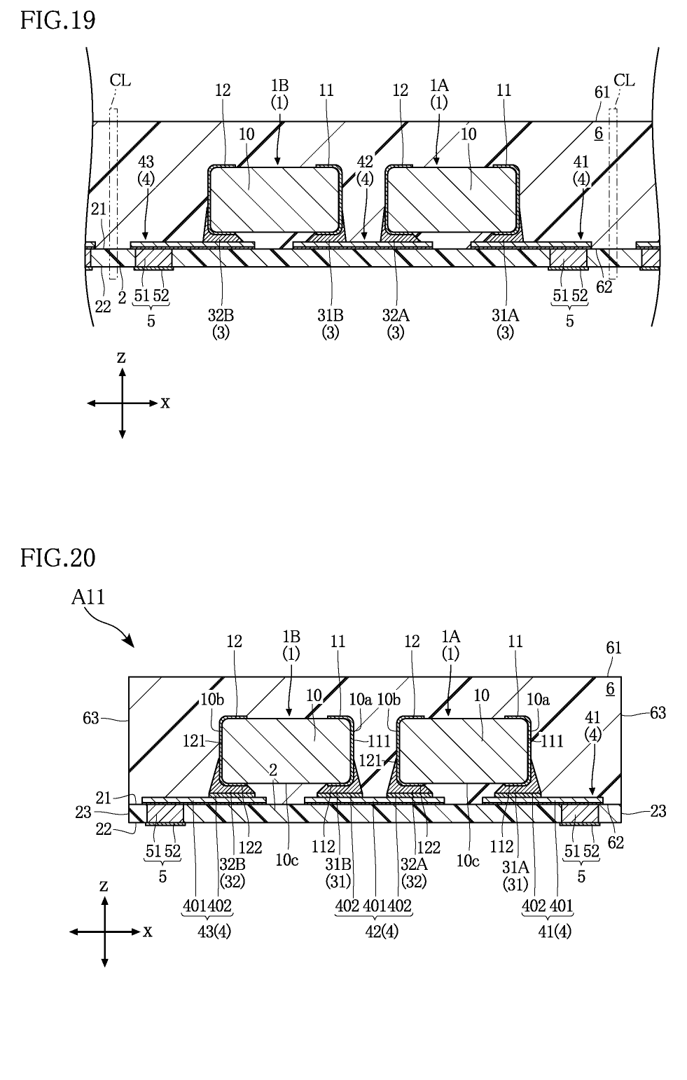

Next, as shown in FIG. 19, the external electrode portions 52 are formed. The external electrode portions 52 are formed on the top surfaces of the columnar portions 51 that are exposed from the reverse surface 22. The external electrode portions 52 are formed by electroless plating, for example. In the electroless plating, an Ni layer, a Pd layer, and an Au layer are stacked in this order to form each external electrode portion 52 from the side in contact with a corresponding columnar portion 51. As a result, the terminals 5, each including a columnar portion 51 and an external electrode portion 52, are formed.

Subsequently, the sealing resin 6 is cut along cut lines CL shown in FIG. 19 and divided into individual pieces. The cutting of the sealing resin 6 may be performed by a dicing process with a dicing blade.

The electronic device A10 shown in FIGS. 1 to 10 is manufactured through the steps as described above. The manufacturing method of the electronic device A10 is not limited to the above example. For example, the electronic device A10 is manufactured as follows when the support member 2 contains a single-crystal intrinsic semiconductor (e.g., Si). First, grooves are formed in the support substrate 80 (silicon wafer) by etching or the like. Next, the columnar portions 51 are formed in the grooves. Then, the wiring layer 4 is formed without forming the support member 2 (resin layer). After the sealing resin 6 is formed, the support substrate 80 is not removed but rather ground until the columnar portions 51 in the grooves are exposed. Changing to such a process enables manufacturing the electronic device A10 in which the support member 2 is made of a semiconductor material.

The functions and advantages of the electronic device A10 are as follows.

The electronic device A10 includes the conductive bonding member 31A as a first conductive bonding member. The conductive bonding member 31A has the top 310 as a first top. The distance d1 (first distance) between the top 310 and the bottom surface 10c of the body 10 in the thickness direction z is at least zero and at most 1/2 of the dimension of the side electrode 111 in the thickness direction z. The side electrode 111 is an example of a "first side electrode". With this configuration, the amount (volume) of the conductive bonding member 31A can be appropriately reduced while ensuring the electrical connection between the terminal 11 and the wiring section 41. This makes it possible to reduce the stress resulting from the volumetric expansion of the conductive bonding member 31A caused by a temperature rise. This suppresses cracks in the electronic device A10, thereby suppressing a decrease in the reliability of the electronic device A10. Suppose that two conductive bonding members 31A have the same volume but one has a larger dimension in the thickness direction z and the other has a smaller dimension in the thickness direction z. In this case, the stress caused by volumetric expansion and applied in the thickness direction z is smaller in the conductive bonding member 31A that has a smaller dimension in the thickness direction z. As a result, the stress applied to the support member 2 is reduced, thus suppressing cracks in the support member 2. This is also the case in the conductive bonding member 31B.

In particular, the distance d1 is (at least zero and) at most 1/4 of the dimension of the side electrode 111 in the thickness direction z. In this configuration, the amount (volume) of the conductive bonding member 31A is further reduced. Thus, it is preferable for the electronic device A10 in terms of reducing the stress resulting from the volumetric expansion of the conductive bonding member 31A caused by a temperature rise.

As described above, in the electronic device A10, the amount (volume) of the conductive bonding member 31A is appropriately reduced in order to reduce the stress resulting from the volumetric expansion of the conductive bonding member 31A caused by a temperature rise. As a result, the dimension of the conductive bonding member 31A in the first direction x is at least 1.0 times and at most 1.5 times the dimension L112 of the bottom electrode 112 in the first direction x. The bottom electrode 112 is an example of a "first bottom electrode". In other words, in the electronic device A10, the dimension of the conductive bonding member 31A in the first direction x is set to at least 1.0 times and at most 1.5 times the dimension L112 of the bottom electrode 112 in the first direction x, so that the amount (volume) of the conductive bonding member 31A can be appropriately reduced while ensuring the electrical connection between the terminal 11 and the wiring section 41. This is also the case in the conductive bonding members 31B, 32A, and 32B.

In the electronic device A10, each of the conductive bonding members 31A and 31B includes a fillet 312. This configuration facilitates visual inspection in the manufacturing process of the electronic device A10 (e.g., before forming the sealing resin 6) to determine whether the terminal 11 of each of the electronic components 1A and 1B is appropriately bonded to the wiring layer 4. Similarly, each of the conductive bonding members 32A and 32B includes a fillet 322. This configuration facilitates visual inspection in the manufacturing process of the electronic device A10 (e.g., before forming the sealing resin 6) to determine whether the terminal 12 of each of the electronic components 1A and 1B is appropriately bonded to the wiring layer 4.

In the electronic device A10, the thickness of the support member 2 is at least 1/20 and at most 1/5 of the thickness of each electronic component 1. The research by the present inventors has shown that the smaller the thickness of the support member 2, the smaller the warpage of the support member 2. On the other hand, the research has also shown that the thicker the support member 2, the smaller the volumetric expansion of the conductive bonding member 31A caused by a temperature rise. Thus, in the electronic device A10, the thickness of the support member 2 is set within the above range (at least 1/20 and at most 1/5), thereby suppressing the volumetric expansion of the conductive bonding member 31A caused by a temperature rise while reducing the warpage of the support member 2.

The electronic device A10 includes the conductive bonding member 32A as a second conductive bonding member. The conductive bonding member 32A has the top 320 as a second top. The distance d2 (second distance) between the top 320 and the bottom surface 10c of the body 10 in the thickness direction z is at least zero and at most 1/2 of the dimension of the side electrode 121 in the thickness direction z. The side electrode 121 is an example of a "second side electrode". With this configuration, the amount (volume) of the conductive bonding member 32A can be appropriately reduced while ensuring the electrical connection between the terminal 12 and the wiring section 42. This makes it possible to reduce the stress resulting from the volumetric expansion of the conductive bonding member 32A caused by a temperature rise. This suppresses cracks in the electronic device A10, thereby suppressing a decrease in the reliability of the electronic device A10. Suppose that two conductive bonding members 32A have the same volume but one has a larger dimension in the thickness direction z and the other has a smaller dimension in the thickness direction z. In this case, the stress caused by volumetric expansion and applied in the thickness direction z is smaller in the conductive bonding member 32A that has a smaller dimension in the thickness direction z. As a result, the stress applied to the support member 2 is reduced, thus suppressing cracks in the support member 2. This is also the case in the conductive bonding member 32B.

In the electronic device A10, as viewed in the first direction x, the positions of the two tops 310 and 320 relative to the electronic components 1A and 1B are the same in the thickness direction z. In other words, the two tops 310 and 320 are located at the same height. With this configuration, the terminals 11 and 12 of the electronic components 1A and 1B are bonded to the wiring layer 4 in the same (or substantially the same) manner. Accordingly, in the electronic device A10, it is possible to prevent the electronic components 1A and 1B from being bonded in a tilted orientation.

In the electronic device A10, the electronic components 1A and 1B are covered with the sealing resin 6. This configuration increases the stress on the support member 2 due to the volumetric expansion of each of the conductive bonding members 3 (the conductive bonding members 31A, 31B, 32A, and 32B), as compared to a configuration without the sealing resin 6. Thus, it is more likely to cause cracks in the support member 2. Accordingly, in the configuration where the electronic components 1A and 1B are covered with the sealing resin 6, reducing the amount of the conductive bonding members 3 (the conductive bonding members 31A, 31B, 32A, and 32B) appropriately and thereby reducing the stress caused by the volumetric expansion of each of the conductive bonding members 3 (the conductive bonding members 31A, 31B, 32A, and 32B) is preferable for suppressing cracks formed in the electronic device A10.

In the electronic device A10, the support member 2 contains insulating resin, and the insulating resin is the same as the material (e.g., epoxy resin) of the sealing resin 6. With this configuration, the coefficient of linear expansion of the support member 2 becomes equal to the coefficient of linear expansion of the sealing resin 6. This makes it possible to suppress the effect of thermal stress in the electronic device A10.

The following describes other embodiments and variations of the electronic device according to the present disclosure. The configurations of the elements in each of the embodiments and the variations can be combined as appropriate as long as the combination does not cause technical contradictions.

FIG. 20 shows an electronic device A11 according to a first variation of the first embodiment. The electronic device A11 is different from the electronic device A10 in that each of the wiring sections 41, 42, and 43 includes a plating layer 402.

As shown in FIG. 20, in the electronic device A11, the wiring section 41 includes a conductive layer 401 and a plating layer 402, the wiring section 42 includes a conductive layer 401 and two plating layers 402, and the wiring section 43 includes a conductive layer 401 and a plating layer 402. Unless otherwise specified, the description of a plating layer 402 given below applies to each of the wiring sections 41, 42, and 43.

The plating layer 402 is stacked on a conductive layer 401. For example, the wettability of the plating layer 402 to a conductive bonding member 3 is higher than the wettability of the conductive layer 401 to the conductive bonding member 3. For example, the plating layer 402 contains Ni.

In the electronic device A11, the terminal 11 of the electronic component 1A is bonded to the plating layer 402 of the wiring section 41 with the conductive bonding member 31A, and the terminal 12 of the electronic component 1A is bonded to one of the two plating layers 402 of the wiring section 42 with the conductive bonding member 32A. In the electronic device A11, the terminal 11 of the electronic component 1B is bonded to the other of the two plating layers 402 of the wiring section 42 with the conductive bonding member 31B, and the terminal 12 of the electronic component 1B is bonded to the plating layer 402 of the wiring section 43 with the conductive bonding member 32B.

In each of the wiring sections 41, 42, and 43, the dimension of the plating layer 402 in the first direction x is not particularly limited, but may be the same (or substantially the same) as the dimension of the corresponding one of the conductive bonding members 31A, 31B, 32A, and 32B in the first direction x. In this example, the dimension of each of the plating layers 402 in the first direction x is at least 1.0 times and at most 1.5 times the dimension L112 of the bottom electrode 112 in the first direction x or the dimension L122 of the bottom electrode 122 in the first direction x.

As with the electronic device A10, the electronic device A11 includes a conductive bonding member 31A as a first conductive bonding member, and the conductive bonding member 31A has a top 310 as a first top. The distance d1 (first distance) between the top 310 and the bottom surface 10c of the body 10 in the thickness direction z is at least zero and at most 1/2 of the dimension of the side electrode 111 in the thickness direction z. Thus, as with the electronic device A10, the electronic device A11 can reduce the stress resulting from the volumetric expansion of the conductive bonding member 31A caused by a temperature rise, thereby suppressing cracks in the electronic device A11. Further, the electronic device A11 has advantages similar to the electronic device A10 owing to its configuration common with the electronic device A10.

In the electronic device A11, each of the wiring sections 41, 42, and 43 includes a plating layer 402, and each of the conductive bonding members (the conductive bonding members 31A, 31B, 32A, and 32B) is bonded to a corresponding plating layer 402. This configuration can suppress the outflow of the conductive bonding members 3 from the plating layers 402 to the conductive layers 401. In the electronic device A10 described above, the amount (volume) of each conductive bonding member 3 is appropriately reduced in order to reduce the stress resulting from the volumetric expansion of the conductive bonding member 3 caused by a temperature rise. In this configuration, the greater the size of each conductive bonding member 3 in plan view, the smaller the dimension of the conductive bonding member 3 in the thickness direction z. Since each plating layer 402 can prevent the plan-view size of the corresponding conductive bonding member 3 from becoming too large, the dimension of the conductive bonding member 3 in the thickness direction z can be ensured appropriately. As such, the electronic device A11 can prevent insufficient thickness of each conductive bonding member 3, and therefore can suppress a decrease in bonding strength between the terminals 11, 12 of the electronic components 1A, 1B and the wiring layer 4, and can also suppress a decrease in electrical conductivity therebetween. In other words, the electronic device A11 can suppress a decrease in reliability.

In the electronic device A11, the wettability of the plating layers 402 to the respective conductive bonding members 3 is higher than the wettability of the conductive layers 401 to the respective conductive bonding members 3. This configuration can suppress the outflow from the plating layers 402 to the conductive layers 401.

In the electronic device A11, the terminal 12 of the electronic component 1A and the terminal 11 of the electronic component 1B are bonded to the wiring section 42. In such a configuration, the two conductive bonding members 32A and 31B are disposed on the wiring section 42. As a result, if unintended outflow of the conductive bonding members 32A and 31B occurs, these two conductive bonding members 32A and 31B become integrated with each other. Such integration facilitates the outflow of the conductive bonding members 32A and 31B, leading to insufficient thickness of each of the conductive bonding members 32A and 31B. Thus, using the plating layers 402 to suppress the outflow of the conductive bonding members 32A and 31B is preferable for preventing insufficient thickness of each of the conductive bonding members 32A and 31B. In other words, the electronic device A11 has a preferable structure for suppressing a decrease in reliability.

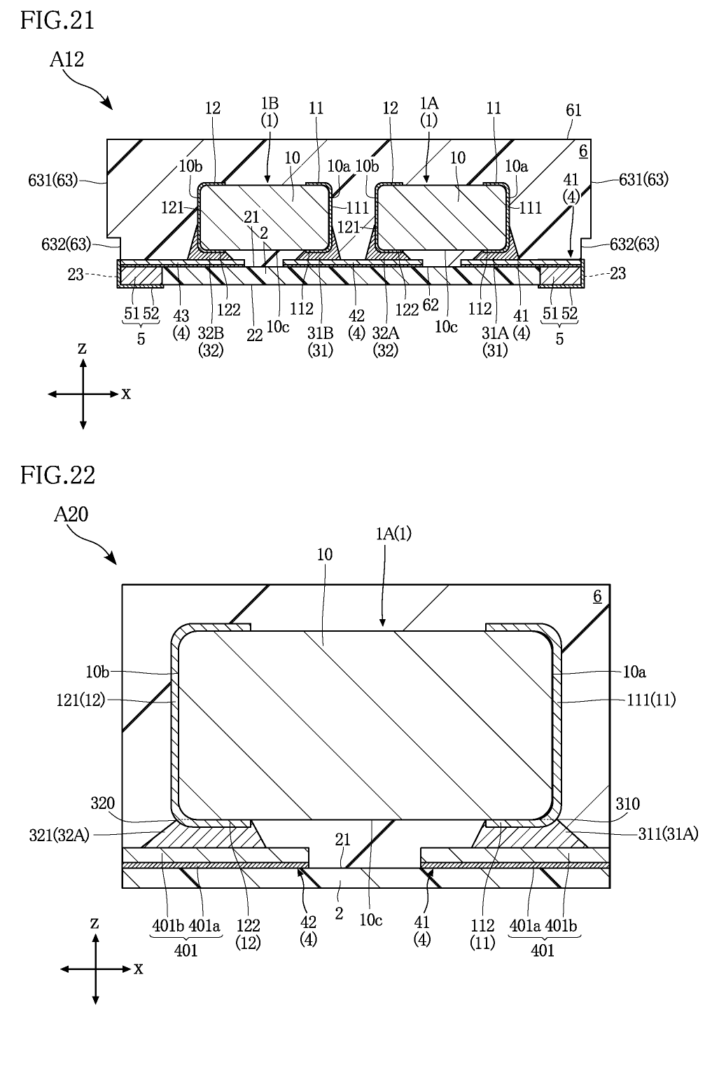

FIG. 21 shows an electronic device A12 according to a second variation of the first embodiment. The electronic device A12 is different from the electronic device A10 in that each resin side surface 63 of the sealing resin 6 in the electronic device A12 has a step.

As shown in FIG. 21, each of the resin side surfaces 63 in the electronic device A12 has a first side portion 631 and a second side portion 632. In each of the resin side surfaces 63, the first side portion 631 and the second side portion 632 face in the same direction. The first side portion 631 is located outward relative to the second side portion 632 in plan view. The first side portion 631 is connected to the resin obverse surface 61, and the second side portion 632 is connected to a corresponding one of the side surfaces 23. The second side portion 632 is flush with the corresponding side surface 23. With this configuration, each of the resin side surfaces 63 has a step.

As shown in FIG. 21, the terminals 5 include one whose columnar portion 51 is exposed from one of the side surfaces 23. In the terminal 5 whose columnar portion 51 is exposed from the side surface 23, the external electrode portion 52 covers the surface of the columnar portion 51 that is exposed from the reverse surface 22 of the support member 2 and the surface of the columnar portion 51 that is exposed from the side surface 23 of the support member 2.

As with the electronic device A10, the electronic device A12 includes a conductive bonding member 31A as a first conductive bonding member, and the conductive bonding member 31A has a top 310 as a first top. The distance d1 (first distance) between the top 310 and the bottom surface 10c of the body 10 in the thickness direction z is at least zero and at most 1/2 of the dimension of the side electrode 111 in the thickness direction z. Thus, as with the electronic device A10, the electronic device A12 can reduce the stress resulting from the volumetric expansion of the conductive bonding member 31A caused by a temperature rise, thereby suppressing cracks in the electronic device A12. Further, the electronic device A12 has advantages similar to the electronic device A10 owing to its configuration common with the electronic device A10.

Further, in the electronic device A12, each of the resin side surfaces 63 of the sealing resin 6 has a step. Due to the step, the terminals 5 include one whose columnar portion 51 is exposed from one of the side surfaces 23. With this configuration, the terminal 5 whose columnar portion 51 is exposed from the side surface 23 has an external electrode portion 52 also formed on the surface of the columnar portion 51 exposed from the side surface 23. Thus, when the electronic device A12 is mounted onto the circuit board of an electronic apparatus or the like, a fillet can be formed in a conductive bonding material (e.g., solder) used for the mounting. In other words, as compared to the electronic device A10, the electronic device A12 facilitates visual inspection to determine whether the electronic device A12 is appropriately bonded to the circuit board of an electronic apparatus or the like.

FIG. 22 shows an electronic device A20 according to a second embodiment. The electronic device A20 is different from the electronic device A10 in the following points. First, the conductive bonding member 31A in the electronic device A20 does not include the fillet 312. Second, the conductive bonding member 32A in the electronic device A20 does not include the fillet 322. In the present embodiment, the illustration of each of the conductive bonding members 31B and 32B is omitted. However, the conductive bonding member 31B may be configured in the same manner as the conductive bonding member 31A in the present embodiment or as the conductive bonding member 31A in the electronic device A10. The conductive bonding member 32B may be configured in the same manner as the conductive bonding member 32A in the present embodiment or as the conductive bonding member 32A in the electronic device A10.

As shown in FIG. 22, the conductive bonding member 31A of the electronic device A20 is configured with the intervening portion 311. In the illustrated example, the top 310 of the conductive bonding member 31A overlaps with the boundary between the side electrode 111 and the bottom electrode 112 of the terminal 11 of the electronic component 1A, as viewed in the first direction x. The conductive bonding member 32A of the electronic device A20 is configured with the intervening portion 321. In the illustrated example, the top 320 of the conductive bonding member 32A overlaps with the boundary between the side electrode 121 and the bottom electrode 122 of the terminal 12 of the electronic component 1A, as viewed in the first direction x.

As with the electronic device A10, the electronic device A20 includes a conductive bonding member 31A as a first conductive bonding member, and the conductive bonding member 31A has a top 310 as a first top. The distance d1 (first distance) between the top 310 and the bottom surface 10c of the body 10 in the thickness direction z is at least zero and at most 1/2 of the dimension of the side electrode 111 in the thickness direction z. Thus, as with the electronic device A10, the electronic device A20 can reduce the stress resulting from the volumetric expansion of the conductive bonding member 31A caused by a temperature rise, thereby suppressing cracks in the electronic device A20. This is also the case in the conductive bonding member 31B. Further, the electronic device A20 has advantages similar to the electronic devices A10 to A12 owing to its configuration common with the electronic devices A10 to A12.

As will be understood from the present embodiment, in the electronic device of the present disclosure, whether or not the fillet 312 is formed in each of the conductive bonding members 31A and 31B is not particularly limited. In the electronic device of the present disclosure, whether or not the fillet 322 is formed in each of the conductive bonding members 32A and 32B is not particularly limited.

The first to second embodiments (including these variations) have been described with an example where the number of electronic components 1 is two. However, in the electronic device of the present disclosure, the number of electronic components 1 may be one or at least three.

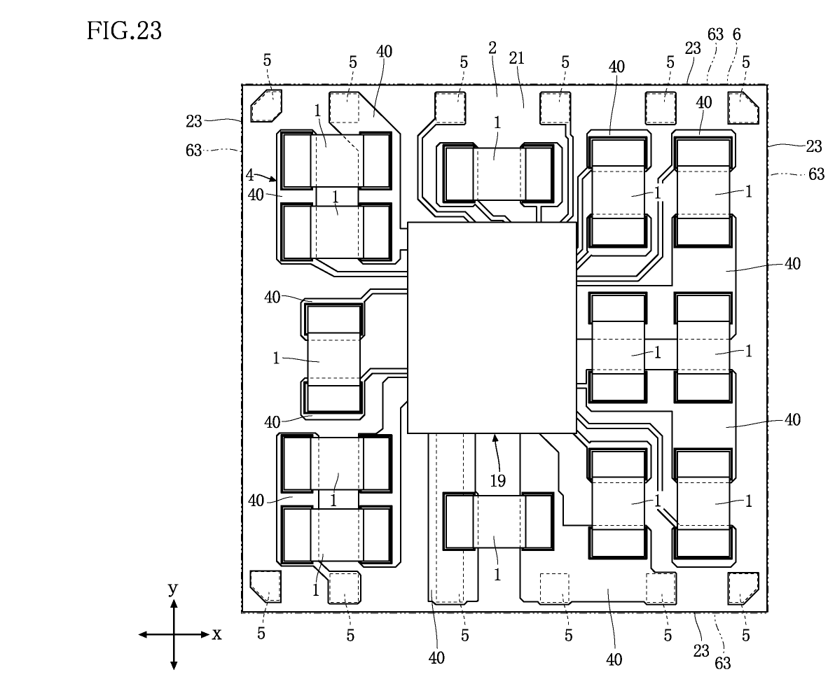

In an example different from the first to second embodiments (including these variations), the electronic device may include a semiconductor element in addition to at least one electronic component 1. FIG. 23 shows an electronic device that further includes a semiconductor element 19. In the electronic device shown in FIG. 23, the wiring layer 4 includes a plurality of wiring sections 40, and each of the electronic components 1 is bonded to two of the wiring sections 40. As a result, the electronic components 1 are electrically connected as appropriate. The semiconductor element 19 is an integrated circuit such as an LSI. Unlike this example, the semiconductor element 19 may be a voltage control element such as a low drop out regulator (LDO), an amplification element such as an operational amplifier, or a discrete element such as a transistor or a diode. In the example shown in FIG. 23, the semiconductor element 19 is flip-chip mounted across some of the wiring sections 40. As a result, the semiconductor element 19 is electrically connected as appropriate to one of the electronic components 1 and one of the terminals 5 via at least one wiring section 40. As will be understood from the present variation, the electronic device of the present disclosure is not limited to including only electronic components, but may further include a semiconductor element.

The electronic device according to the present disclosure is not limited to the above embodiments. Various design changes can be made to the specific configurations of the elements of the electronic device according to the present disclosure. The present disclosure includes the embodiments described in the following clauses.

### Clause 1.

An electronic device comprising: an electronic component that includes a body and a first terminal; a support member that supports the electronic component; a wiring layer that includes a first wiring section, and that is formed on the support member; and a first conductive bonding member that bonds the first terminal to the first wiring section, wherein the electronic component is located on a first side in a thickness direction of the electronic component relative to the wiring layer, the body includes a first side surface facing a first side in a first direction perpendicular to the thickness direction, and a bottom surface connected to the first side surface and facing the support member, the first terminal includes a first side electrode covering the first side surface, the first side electrode extends from a first edge to a second edge of the first side surface in the thickness direction, the first conductive bonding member includes a first top located on the first side in the thickness direction, and a first distance between the first top and the bottom surface in the thickness direction is at least zero and at most 1/2 of a dimension of the first side electrode in the thickness direction.

### Clause 2.

The electronic device according to clause 1, wherein the first conductive bonding member includes a first intervening portion located between the electronic component and the first wiring section in the thickness direction, and a first fillet including the first top and connected to the first intervening portion, and the first fillet covers a part of the first side electrode.

### Clause 3.

The electronic device according to clause 1 or 2, wherein the first distance is at most 1/4 of the dimension of the first side electrode in the thickness direction.

### Clause 4.

The electronic device according to any of clauses 1 to 3, wherein the first terminal includes a first bottom electrode covering a part of the bottom surface and connected to the first side electrode, and a dimension of the first conductive bonding member in the first direction is at least 1.0 times and at most 1.5 times a dimension of the first bottom electrode in the first direction.

### Clause 5.

The electronic device according to clause 4, wherein the first wiring section includes a conductive layer stacked on the support member and a plating layer stacked on the conductive layer, and the first conductive bonding member is in contact with the plating layer.

### Clause 6.

The electronic device according to clause 5, wherein a wettability of the plating layer to the first conductive bonding member is higher than a wettability of the conductive layer to the first conductive bonding member.

### Clause 7.

The electronic device according to clause 5 or 6, wherein a dimension of the plating layer in the first direction is at least 1.0 times and at most 1.5 times the dimension of the first bottom electrode in the first direction.

### Clause 8.

The electronic device according to any of clauses 1 to 7, wherein a dimension of the support member in the thickness direction is at least 1/20 and at most 1/5 of a dimension of the electronic component in the thickness direction.

### Clause 9.

The electronic device according to any of clauses 1 to 8, further comprising a second conductive bonding member, wherein the wiring layer includes a second wiring section spaced apart from the first wiring section, the electronic component includes a second terminal spaced apart from the first terminal, and the second conductive bonding member bonds the second terminal to the second wiring section.

### Clause 10.

The electronic device according to clause 9, wherein the body includes a second side surface connected to the bottom surface and facing a second side in the first direction, the second side electrode extends from a first edge to a second edge of the second side surface in the thickness direction, the second conductive bonding member includes a second top located on the first side in the thickness direction, and a second distance between the second top and the bottom surface in the thickness direction is at least zero and at most 1/2 of a dimension of the second side electrode in the thickness direction.

### Clause 11.

The electronic device according to clause 10, wherein as viewed in the first direction, the first top and the second top are located at a same position in the thickness direction.

### Clause 12.

The electronic device according to clause 10 or 11, wherein the second conductive bonding member includes a second intervening portion located between the electronic component and the second wiring section in the thickness direction, and a second fillet including the second top and connected to the second intervening portion, and the second fillet covers a part of the second side electrode.

### Clause 13.

The electronic device according to any of clauses 10 to 12, wherein the second terminal includes a second bottom electrode covering a part of the bottom surface and connected to the second side electrode.

### Clause 14.

The electronic device according to any of clauses 1 to 13, further comprising a sealing resin formed on the support member, wherein the sealing resin covers the electronic component.

### Clause 15.

The electronic device according to clause 14, wherein the sealing resin contains an epoxy resin.

### Clause 16.

The electronic device according to clause 14 or 15, wherein the support member contains an insulating resin.

### Clause 17.

The electronic device according to clause 16, wherein the support member contains a same material as the sealing resin.

### REFERENCE NUMERALS

A10, A11, A12, A20: Electronic device 1, 1A, 1B: Electronic component 10: Body 10a: Side surface 10b: Side surface 10c: Bottom surface 11, 12: Terminal 111, 121: Side electrode 112, 122: Bottom electrode 19: Semiconductor element 2: Support member 21: Mounting surface 22: Reverse surface 23: Side surface 3, 31A, 31B, 32A, 32B: Conductive bonding member 310, 320: Top 311, 321: Intervening portion 312, 322: Fillet 4: Wiring layer 40, 41, 42, 43: Wiring section 401: Conductive layer 401a: Seed layer 401b: Metal layer 402: Plating layer 5: Terminal 51: Columnar portion 52: External electrode portion 6: Sealing resin 61: Resin obverse surface 62: Resin reverse surface 63: Resin side surface 631: First side portion 632: Second side portion 80: Support substrate 80a: Substrate obverse surface 80b: Substrate reverse surface CL: Cut line

1. An electronic device comprising:
an electronic component that includes a body and a first terminal;
a support member that supports the electronic component;
a wiring layer that includes a first wiring section, and that is formed on the support member; and
a first conductive bonding member that bonds the first terminal to the first wiring section,
wherein the electronic component is located on a first side in a thickness direction of the electronic component relative to the wiring layer,
the body includes a first side surface facing a first side in a first direction perpendicular to the thickness direction, and a bottom surface connected to the first side surface and facing the support member,
the first terminal includes a first side electrode covering the first side surface,
the first side electrode extends from a first edge to a second edge of the first side surface in the thickness direction,
the first conductive bonding member includes a first top located on the first side in the thickness direction, and
a first distance between the first top and the bottom surface in the thickness direction is at least zero and at most 1/2 of a dimension of the first side electrode in the thickness direction.

2. The electronic device according to claim 1, wherein the first conductive bonding member includes a first intervening portion located between the electronic component and the first wiring section in the thickness direction, and a first fillet including the first top and connected to the first intervening portion, and
the first fillet covers a part of the first side electrode.

3. The electronic device according to claim 1, wherein the first distance is at most 1/4 of the dimension of the first side electrode in the thickness direction.

4. The electronic device according to claim 1, wherein the first terminal includes a first bottom electrode covering a part of the bottom surface and connected to the first side electrode, and
a dimension of the first conductive bonding member in the first direction is at least 1.0 times and at most 1.5 times a dimension of the first bottom electrode in the first direction.

5. The electronic device according to claim 4, wherein the first wiring section includes a conductive layer stacked on the support member and a plating layer stacked on the conductive layer, and
the first conductive bonding member is in contact with the plating layer.

6. The electronic device according to claim 5, wherein a wettability of the plating layer to the first conductive bonding member is higher than a wettability of the conductive layer to the first conductive bonding member.

7. The electronic device according to claim 5, wherein a dimension of the plating layer in the first direction is at least 1.0 times and at most 1.5 times the dimension of the first bottom electrode in the first direction.

8. The electronic device according to claim 1, wherein a dimension of the support member in the thickness direction is at least 1/20 and at most 1/5 of a dimension of the electronic component in the thickness direction.

9. The electronic device according to claim 1, further comprising a second conductive bonding member,
wherein the wiring layer includes a second wiring section spaced apart from the first wiring section,
the electronic component includes a second terminal spaced apart from the first terminal, and
the second conductive bonding member bonds the second terminal to the second wiring section.

10. The electronic device according to claim 9, wherein the body includes a second side surface connected to the bottom surface and facing a second side in the first direction,
the second terminal includes a second side electrode covering the second side surface,
the second side electrode extends from a first edge to a second edge of the second side surface in the thickness direction,
the second conductive bonding member includes a second top located on the first side in the thickness direction, and
a second distance between the second top and the bottom surface in the thickness direction is at least zero and at most 1/2 of a dimension of the second side electrode in the thickness direction.

11. The electronic device according to claim 10, wherein as viewed in the first direction, the first top and the second top are located at a same position in the thickness direction.

12. The electronic device according to claim 10, wherein the second conductive bonding member includes a second intervening portion located between the electronic component and the second wiring section in the thickness direction, and a second fillet including the second top and connected to the second intervening portion, and
the second fillet covers a part of the second side electrode.

13. The electronic device according to claim 10, wherein the second terminal includes a second bottom electrode covering a part of the bottom surface and connected to the second side electrode.

14. The electronic device according to claim 1, further comprising a sealing resin formed on the support member,
wherein the sealing resin covers the electronic component.

15. The electronic device according to claim 14, wherein the sealing resin contains an epoxy resin.

16. The electronic device according to claim 14, wherein the support member contains an insulating resin.

17. The electronic device according to claim 16, wherein the support member contains a same material as the sealing resin.
